(19) United States
(12) Patent Application Publication
(10) Pub. No.: US 2024/0079352 A1
(43) Pub. Date: Mar. 7, 2024

(54) INTEGRATED CIRCUIT (IC) PACKAGES EMPLOYING CAPACITOR INTERPOSER SUBSTRATE WITH ALIGNED EXTERNAL INTERCONNECTS, AND RELATED FABRICATION METHODS

(71) Applicant: QUALCOMM Incorporated, San Diego, CA (US)

(72) Inventors: Jihong Choi, San Diego, CA (US); Giridhar Nallapati, San Diego, CA (US); Lily Zhao, San Diego, CA (US); Dongming He, San Diego, CA (US)

(21) Appl. No.: 17/929,408

(22) Filed: Sep. 2, 2022

(51) Int. Cl. H01L 23/64; H01L 21/48; H01L 23/00; H01L 23/498; H01L 25/16

(52) U.S. Cl. CPC H01L 23/642; H01L 21/4853; H01L 21/4857; H01L 21/486; H01L 23/49816; H01L 23/49822; H01L 23/49833; H01L 23/49838; H01L 24/16; H01L 24/17; H01L 24/32; H01L 24/73; H01L 24/96; H01L 24/97; H01L 25/16; H01L 2224/16235; H01L 2224/17163; H01L 2224/32225; H01L 2224/73204; H01L 2924/19041; H01L 2924/30101; H01L 2924/30105; H01L 2924/30107

(57) ABSTRACT

Aspects disclosed herein include integrated circuit (IC) packages employing a capacitor interposer substrate with aligned external interconnects, and related fabrication methods. The IC package includes one or more semiconductor dies (“dies”) electrically coupled to a package substrate that supports electrical signal routing to and from the die(s). The capacitor interposer substrate is disposed between the die(s) and the package substrate. The die(s) is coupled to embedded capacitor(s) in the capacitor interposer substrate through die interconnects coupled to external interconnects of the capacitor interposer substrate. In exemplary aspects, the external interconnects on the outer surfaces of the capacitor interposer substrate are aligned. In this manner, the capacitor interposer substrate can maintain interconnect compatibility to the die(s) and package substrate if the die(s) and package substrate have a pattern of die interconnects and external interconnects that are designed to align with each other when coupled to each other.

### BACKGROUND

### Field of the Disclosure

The field of the disclosure relates to integrated circuit (IC) packages, and more particularly to providing decoupling capacitance in a power distribution network (PDN) of the IC package for reducing current-resistance (IR) drop and voltage droop.

### II. BACKGROUND

Integrated circuits (ICs) are the cornerstone of electronic devices. ICs are typically packaged in an IC package, also called a “semiconductor package” or “chip package.” The IC package includes a package substrate and one or more IC chips or other electronic modules mounted to the package substrate to provide electrical connectivity to the IC chips. For example, an IC chip in an IC package may be a system-on-a chip (SoC). The IC chips are electrically coupled to other IC chips and/or to other components in the IC package through electrical coupling to metal lines in the package substrate. The IC chips can also be electrically coupled to other circuits outside the IC package through electrical connections of external metal interconnects (e.g., solder bumps) of the IC package.

High-performance computer chips in IC packages require effective power distribution networks (PDN) to distribute power to the circuits and other components in the IC chip efficiently. For example, an IC package may include a separate power management chip (PMC) that includes voltage regulator circuitry configured to distribute voltage to other IC chips in the IC package. Noise can occur in the PDN due to current-resistance (IR) drop between the PMC and a powered IC chip due to the series resistance and inductance in the PDN. Change in current draw from a powered IC chip to the PDN can induce noise in the PDN. If the magnitude of noise in the PDN exceeds a certain threshold, it alters the voltages delivered to the IC chips and its circuits below the acceptable values, which can cause malfunction of circuits. Even if a PDN supplies a voltage to the IC chips within tolerance, the PDN noise may still cause other problems. It can cause or appear as crosstalk on signal lines. Further, as PDN interconnects typically carry higher currents, high-frequency PDN noise has the potential of creating electromagnetic radiation interference, possibly causing other failures.

Thus, it is important to control noise in a PDN. In this regard, decoupling capacitors are employed to shunt PDN noise in the PDN to reduce its effect on the IC chips powered by the PDN. A decoupling capacitor can be mounted on a package substrate or embedded within a package substrate of an IC package to provide decoupling capacitance between the power source and IC chips. However, the electrical path connection between the decoupling capacitor and the IC chips has a parasitic inductance that can contribute to IR drop and PDN noise in an undesired manner.

### SUMMARY OF THE DISCLOSURE

Aspects disclosed herein include integrated circuit (IC) packages employing a capacitor interposer substrate with aligned external interconnects. The capacitor interposer substrates configured to be included in an IC package to interconnect a die(s) to a package substrate through the aligned external interconnects and to provide a capacitor(s) to be coupled to a circuit in the die(s). Related fabrication methods are also disclosed. As an example, the capacitor interposer substrate includes embedded capacitor(s) that can provide a decoupling capacitance for a power distribution network (PDN) in the IC package to reduce current-resistance (IR) drop. The IC package includes one or more semiconductor dies (“dies”) electrically coupled to a package substrate that supports electrical signal routing to and from the die(s). In exemplary aspects, the capacitor interposer substrate is disposed between the die(s) and the package substrate to minimize the distance between embedded capacitor(s) in the capacitor interposer substrate and the die(s). This can reduce parasitic inductance in power signals between the embedded capacitor(s) and the die(s), which can reduce the IR drop in the PDN and in turn reduce PDN noise. The die(s) is coupled to one or more embedded capacitor(s) in the capacitor interposer substrate through die interconnects coupled to external interconnects of the capacitor interposer substrate. The capacitor interposer substrate also has external interconnects exposed from its outer surfaces adjacent to the die(s) and the package substrate to provide electrical through-connections between the die(s) and the package substrate. In exemplary aspects, the external interconnects on the outer surfaces of the capacitor interposer substrate are aligned. For example, the external interconnects on the outer surfaces of the capacitor interposer substrate can have the same pitch and layout locations in a horizontal direction so that each external interconnect is at least partially vertically aligned to another external interconnect on an opposite outer surface of the capacitor interposer substrate.

In this manner, the capacitor interposer substrate can maintain interconnect compatibility to the die(s) and package substrate if the die(s) and package substrate have a pattern of die interconnects and external interconnects that are designed to align with each other when coupled to each other. For example, the die(s) and package substrate may be designed to be directly coupled to each other in an IC package that does not include the capacitor interposer substrate. Thus, the interposer capacitor substrate, by including vertically aligned external interconnects, can be used to electrically couple such die(s) to the package substrate without having to change the layout design of the die interconnects of the die(s) and the external, metal interconnects of the package substrate.

In this regard, in one exemplary aspect, an IC package is provided. The IC package comprises an interposer substrate comprising a first surface and a second surface opposite of the first surface. The interposer substrate further comprises a first metallization layer comprising a plurality of first metal interconnects exposed from the first surface. The interposer substrate also further comprises a second metallization layer comprising a plurality of second metal interconnects exposed from the second surface. The interposer substrate also further comprises a substrate layer disposed between the first metallization layer and the second metallization layer in a first direction, the substrate layer comprising one or more capacitors. Each first metal interconnect of the plurality of first metal interconnects intersects a first axis in the first direction that intersects a second metal interconnect of the plurality of second metal interconnects. The IC package also comprises a package substrate coupled to the first surface of the interposer substrate. The IC package also comprises a die coupled to the second surface of the interposer substrate.

In another exemplary aspect, a method of fabricating a plurality of IC packages, comprising for each IC package of one or more IC packages is provided. The method comprises forming an interposer substrate comprising forming a first metallization layer comprising a plurality of first metal interconnects exposed from a first surface and intersecting a first axis in a first direction, forming a substrate layer adjacent to the first metallization layer, the substrate layer comprising one or more capacitors, and forming a second metallization layer adjacent to the substrate layer such that the substrate layer is disposed between the first metallization layer and the second metallization layer in the first direction, the second metallization layer comprising a plurality of second metal interconnects exposed from a second surface opposite the first surface and intersecting the first axis in the first direction. The method also comprises coupling a package substrate to the first surface of the interposer substrate. The method also comprises coupling one or more dies to the second surface of the interposer substrate.

### BRIEF DESCRIPTION OF THE FIGURES

FIG. 1 is a side view of an exemplary integrated circuit (IC) package that includes a semiconductor die (“die”) mounted on a package substrate, wherein the IC package also includes capacitors mounted to and embedded in the package substrate and coupled to the die;

FIG. 2 is a side view of an exemplary IC package that includes a capacitor interposer substrate coupled to and disposed between a die and a package substrate, wherein capacitor interposer substrate has aligned external interconnects to maintain interconnect compatibility between the die(s) and the package substrate;

FIG. 3 is a side view of an exemplary capacitor interposer substrate that can be the capacitor interposer substrate in FIG. 2 to further illustrate the alignment of external interconnects;

FIG. 4 is a side view of a portion of the capacitor interposer substrate in FIGS. 2 and 3, and illustrating an exemplary capacitor (DTC) embedded in the capacitor interposer substrate;

FIG. 5 is a flowchart illustrating an exemplary process of fabricating an IC package that includes a capacitor interposer substrate coupled to and disposed between a die and a package substrate, wherein the capacitor interposer substrate has aligned external interconnects to maintain interconnect compatibility between the die(s) and the package substrate, including, but not limited to, the IC packages and the capacitor interposer substrates in FIGS. 2-4;

FIGS. 6A and 6B is a flowchart illustrating another exemplary fabrication process of fabricating an IC package that includes a capacitor interposer substrate coupled to and disposed between a die and a package substrate, wherein the capacitor interposer substrate has aligned external interconnects to maintain interconnect compatibility between the die(s) and the package substrate, including, but not limited to, the IC packages and capacitor interposer substrates in FIGS. 2-4;

FIGS. 7A-7E are exemplary fabrication stages during fabrication of an IC package according to the exemplary fabrication process in FIGS. 6A and 6B;

FIG. 8 is a block diagram of an exemplary electronic device in the form of a processor-based system that can include an IC package that includes a capacitor interposer substrate coupled to and disposed between a die and a package substrate, wherein capacitor interposer substrate has aligned external interconnects to maintain interconnect compatibility between the die(s) and package substrate, including, but not limited to, the IC packages and capacitor interposer substrates in FIGS. 2-4, and fabricated according to a fabrication process, including but not limited to the exemplary fabrication processes in FIGS. 5-6B; and

FIG. 9 is a block diagram of an exemplary wireless communications device that includes electrical components formed from one or more IC packages that can include an IC package that includes a capacitor interposer substrate coupled to and disposed between a die and a package substrate, wherein the capacitor interposer substrate has aligned external interconnects to maintain interconnect compatibility between the die(s) and the package substrate, including, but not limited to, the IC packages and capacitor interposer substrates in FIGS. 2-4, and fabricated according to a fabrication process, including but not limited to the exemplary fabrication processes in FIGS. 5-6B.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include integrated circuit (IC) packages employing a capacitor interposer substrate with aligned external interconnects. The capacitor interposer substrate s configured to be included in an IC package to interconnect a die(s) to a package substrate through the aligned external interconnects and to provide a capacitor(s) to be coupled to a circuit in the die(s). Related fabrication methods are also disclosed. As an example, the capacitor interposer substrate includes embedded capacitor(s) that can provide a decoupling capacitance for a power distribution network (PDN) in the IC package to reduce current-resistance (IR) drop. The IC package includes one or more semiconductor dies (“dies”) electrically coupled to a package substrate that supports electrical signal routing to and from the die(s). In exemplary aspects, the capacitor interposer substrate is disposed between the die(s) and the package substrate to minimize the distance between embedded capacitor(s) in the capacitor interposer substrate and the die(s). This can reduce parasitic inductance in power signals between the embedded capacitor(s) and the die(s), which can reduce the IR drop in the PDN and in turn reduce PDN noise. The die(s) is coupled to embedded capacitor(s) in the capacitor interposer substrate through die interconnects coupled to external interconnects of the capacitor interposer substrate. The capacitor interposer substrate also has external interconnects exposed from its outer surfaces adjacent to the die(s) and the package substrate to provide electrical through-connections between the die(s) and the package substrate. In exemplary aspects, the external interconnects on the outer surfaces of the capacitor interposer substrate are aligned. For example, the external interconnects on the outer surfaces of the capacitor interposer substrate can have the same pitch and layout locations in a horizontal direction so that each external interconnect is at least partially vertically aligned to another external interconnect on an opposite outer surface of the capacitor interposer substrate.

In this manner, the capacitor interposer substrate can maintain interconnect compatibility to the die(s) and package substrate if the die(s) and package substrate have a pattern of die interconnects and external interconnects that are designed to align with each other when coupled to each other. For example, the die(s) and package substrate may be designed to be directly coupled to each other in an IC package that does not include the capacitor interposer substrate. Thus, the interposer capacitor substrate, by including vertically aligned external interconnects, can be used to electrically couple such die(s) to the package substrate without having to change the layout design of the die interconnects of the die(s) and the external, metal interconnects of the package substrate.

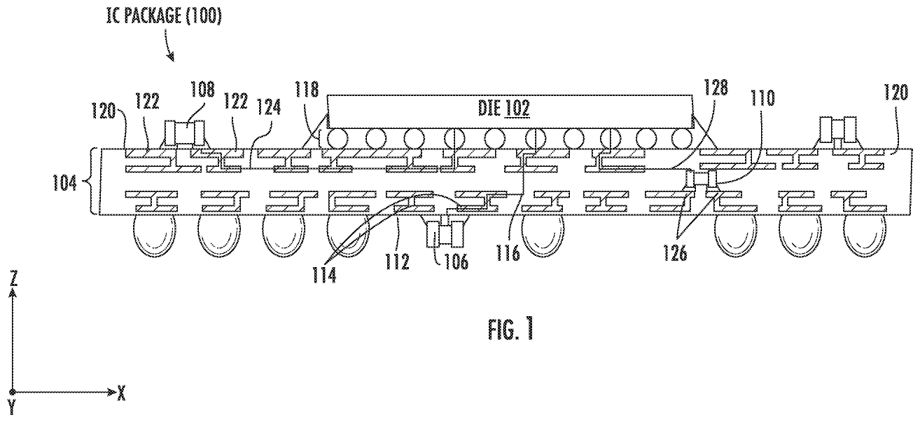

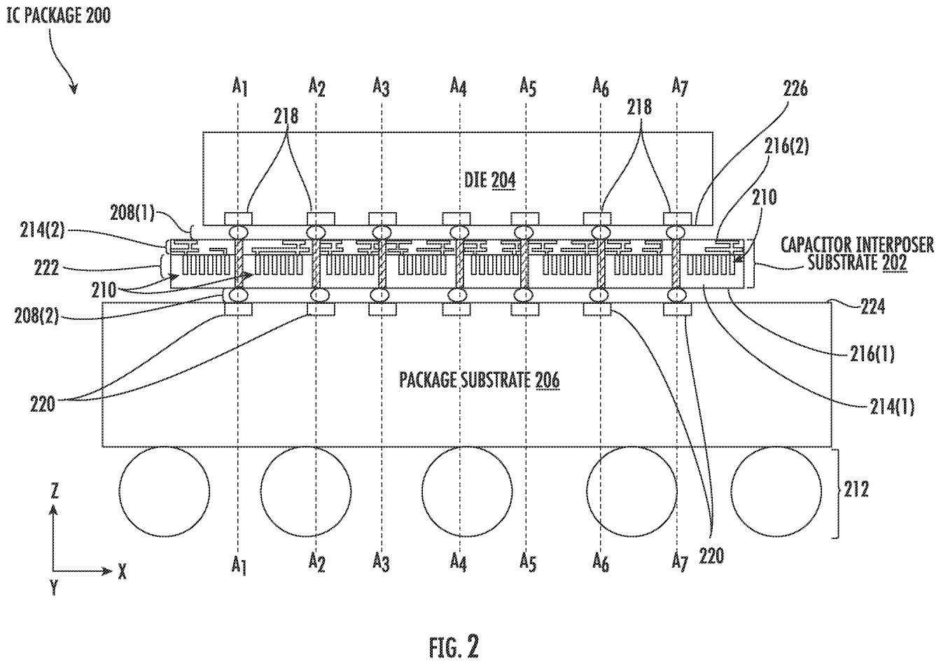

Before discussing examples of IC packages employing a capacitor interposer substrate with aligned external interconnects for interconnecting between a die(s) and a package substrate starting at FIG. 2, an example of an IC package that includes a package substrate that includes deep trench capacitors (DTCs) without employing a separate capacitor interposer substrate is discussed with regard to FIG. 1.

FIG. 1 is a side view of an exemplary integrated circuit (IC) package 100 that includes a semiconductor die (“die”) 102 mounted on a package substrate 104, wherein the IC package 100 also includes capacitors that are mounted to and embedded in the package substrate 104 and coupled to the die 102. In this regard, the IC package 100 includes DTCs in the form of a land-side capacitor (LSC) 106, a die-side capacitor (DSC) 108, and a package substrate embedded DTC 110. The LSC 106, DSC 108, and/or embedded DTC 110 may be provided in the IC package 100 to be coupled to circuits in the die 102 to shunt noise from one electrical circuit (e.g., a power supply circuit) to another electrical circuit (e.g., a powered electrical circuit), or as part of a filtering circuit in the die 102, as examples. A DTC is formed similar to a semiconductor device, and thus has the advantage of being able to be fabricated using semiconductor fabrication methods. An advantage of using DTCs is that they can be placed closer to the die 102 in the IC package 100.

The LSC 106 is mounted on a bottom surface 112 of the package substrate 104. The LSC 106 is electrically coupled to the die 102 by the LSC 106 being coupled to metal interconnects 114 that are coupled to metal lines 116 in a metallization layer(s) of the package substrate 104. The metal lines 116 are directly or indirectly coupled to die interconnects 118 to couple the LSC 106 to the die 102. The DSC 108 is mounted on a top surface 120 of the package substrate 104 in this example. Thus, to not interfere with the die 102, the DSC 108 is mounted to the package substrate 104 in an area that is laterally displaced from the die 102 in the horizontal direction (X- and Y-axes directions). The DSC 108 is also electrically coupled to the die 102 by the DSC 108 being coupled to metal interconnects 122 that are coupled to metal lines 124 in a metallization layer(s) of the package substrate 104. The metal lines 124 are coupled directly or indirectly to die interconnects 118 to couple the DSC 108 to the die 102. The embedded DTC 110 is embedded in the package substrate 104 of the IC package 100. The embedded DTC 110 is also electrically coupled to the die 102 by the embedded DTC 110 being coupled to metal interconnects 126 that are coupled to metal lines 128 in a metallization layer(s) of the package substrate 104. The metal lines 128 are coupled directly or indirectly to the die interconnects 118 to couple the embedded DTC 110 to the die 102.

Even with the IC package 100 in FIG. 1 having the ability to include the LSC 106, DSC 108, and/or embedded DTC 110, these capacitors are still located a distance away from the die 102. This causes signals carried over the metal lines 116, 124, 128 between the respective LSC 106, DSC 108, and embedded DTC 110 and the die 102 to be longer in length, thereby increasing signal path resistance resulting in additional signal delay in such signals. This also leads to less efficient signal routing and use of routing space in the package substrate 104. This could also lead to an increase in number of metallization layers needed in the package substrate 104 to provide sufficient signal routing, thereby adding area and cost to the package substrate 104.

FIG. 2 is a side view of an exemplary IC package 200 that includes a capacitor interposer substrate 202 (“interposer substrate 202”) with aligned external, first and second metal interconnects 208(1), 208(2) for interconnecting between a die 204 and a package substrate 206. In this example, because the interposer substrate 202 is disposed between the die 204 and the package substrate 206 in a first, vertical direction (Z-axis direction), the external first and second metal interconnects 208(1), 208(2) are also aligned in the first, vertical direction (Z-axis direction). Discussion of options for alignment of external, first and second metal interconnects 208(1), 208(2) of the interposer substrate 202 are discussed in more detail below. By providing the interposer substrate 202 with aligned external, first and second metal interconnects 208(1), 208(2), the interposer substrate 202 can maintain interconnect compatibility to the die 204 and the package substrate 206. For example, the die 204 and the package substrate 206 may have a pattern of die interconnects and external interconnects that are designed to align with each other if directly coupled to each other. The die 204 and the package substrate 206 may be designed to be directly coupled to each other in an IC package that does not include the interposer substrate 202. Thus, the interposer substrate 202, by including aligned external interconnects 208(1), 208(2), can be used to electrically couple the die 204 to the package sub state 206 without having to change the layout design of the interconnects of the die 204 and the package substrate 206. This may be useful to avoid having to produce additional stock keeping units (SKUs) of dies and package substrates that can be employed in IC packages, like the IC package 200 in FIG. 2, that includes or does not include a capacitor interposer substrate.

In this regard, as shown in FIG. 2, the IC package 200 includes the interposer substrate 202 coupled to and disposed between the die 204 and the package substrate 206 to make a capacitor(s) available for connection to a circuit(s) in the die 204. The interposer substrate 202 is disposed between the die 204 and the package substrate 206 in a first, vertical direction (Z-axis direction). This can allow the footprint area of the IC package 200 to be minimized in the horizontal directions (X- and Y-axis directions), as opposed to providing the capacitor interposer substrate adjacent to the die 204 in a horizontal direction (X- and Y-axis directions). The interposer substrate 202 includes one or more embedded capacitors 210, which may be deep trench capacitors (DTC) as an example. As an example, the embedded capacitors 210 can be coupled to the package substrate 206 and the die 204 as part of a power distribution network (PDN) to provide a decoupling capacitance for the PDN to reduce IR drop. The die 204 can include circuitry for a specific type of application, such as a radio frequency (RF) transceiver or a computer-based system-on-a-chip (SoC), as non-limiting examples. The package substrate 206 supports the die 204 of the IC package 200 and includes one or more metal layers of metal lines to provide electrical coupling paths between the die 204 and external interconnects 212 to support signaling between the die 204 and other circuits external to the IC package 200. For example, the package substrate 206 includes external interconnects 212 that can be coupled to a printed circuit board (PCB) for example, to interconnect the IC package 200 and its die 204 to other circuits coupled to the PCB. The package substrate 206 can be formed from layers of organic material laminates with metal traces formed therein that are then laminated together as one example. The package substrate 206 can also include a RDL layer to support fan-out of electrical connections as another example.

In this example, to connect the capacitors 210 of the interposer substrate 202 to circuits in the die 204, the interposer substrate 202 includes the second metal interconnects 208(2) in a second metallization layer 214(2) that are exposed from an external, second surface 216(2) of the interposer substrate 202. The second metal interconnects 208(2) can be solder bumps, solder joints, ball grid array (BGA) interconnects, or other metal bumps, as examples. The die 204 is disposed adjacent to the second surface 216(2) of the interposer substrate 202. The die 204 includes die interconnects 218 that are aligned and coupled to the second metal interconnects 208(2) exposed from the second surface 216(2) of the interposer substrate 202, to electrically couple the die 204 to the interposer substrate 202. In this example, the die interconnects 218 of the die 204 are also physically coupled to the second metal interconnects 208(2) to physically couple the die 204 to the second surface 216(2) of the interposer substrate 202. Some of the second metal interconnects 208(2) are coupled to embedded capacitors 210 in the interposer substrate 202 so that the die 204 can be coupled to these embedded capacitors 210 through die interconnects 218 being coupled to such second metal interconnects 208(2).

With continuing reference to FIG. 2, the interposer substrate 202 also includes the first metal interconnects 208(1) in a first metallization layer 214(1) that are exposed from an external, first surface 216(1) of the interposer substrate 202, opposite of the external, second surface 216(2) in the vertical direction (Z-axis direction). The first metal interconnects 208(1) can be solder bumps, solder joints, ball grid array (BGA) interconnects, or other metal bumps, as examples. The capacitors 210 are disposed in a substrate layer 222 that is disposed between the first and second metallization layers 214(1), 214(2) in the interposer substrate 202 in the first, vertical direction (Z-axis direction). The package substrate 206 is disposed adjacent to the first surface 216(1) of the interposer substrate 202. The package substrate 206 includes metal interconnects 220 that are aligned and coupled to the first metal interconnects 208(1) exposed from the external, first surface 216(1) of the interposer substrate 202, to electrically couple the package substrate 206 to first surface 216(1) of the interposer substrate 202. In this example, the metal interconnects 220 of the package substrate 206 are also physically coupled to the first metal interconnects 208(1) of the interposer substrate 202 to physically couple the interposer substrate 202 to the package substrate 206. Some of the first metal interconnects 208(1) can also be coupled to embedded capacitors 210 in the interposer substrate 202 so that the package substrate 206 can be coupled to these embedded capacitors 210 through metal interconnects 220 being coupled to such first metal interconnects 208(1).

With continuing reference to FIG. 2, as discussed above, it may also be desired to provide electrical connections between the die 204 and the package substrate 206. This is so the package substrate 206 can support signal routing between circuits in the die 204 as well as support external signal routing between the external interconnects 212 of the IC package 200 and the die 204. However, because the interposer substrate 202 is disposed between the die 204 and the package substrate 206, it is desired to provide through-connections in the interposer substrate 202 so that the electrical connections can be made, through the interposer substrate 202, between the die 204 and the package substrate 206. However, as also discussed above, it is desired that the pin compatibility between the die interconnects 218 of the die 204 and the metal interconnects 220 of the package substrate 206 be maintained in this example, even with the presence of the interposer substrate 202. Thus, as shown in FIG. 2, in this example, each of the first metal interconnects 208(1) of the interposer substrate 202 coupled to the package substrate 206 are aligned in the first, vertical direction (Z-axis direction) with a second metal interconnect 208(2) among the second metal interconnects 208(2) coupled to the die 204. In this example, each of the first metal interconnects 208(1) intersect a respective first, vertical axis A₁-Ai that also intersects a second metal interconnect 208(2). Thus, in this example, if the vertical space between the first and second metal interconnects 208(1), 208(2) were extended vertically in the first, vertical direction (Z-axis direction), the first and second metal interconnects 208(1), 208(2) would at least partially overlap each other in such vertical space.

The package substrate 206 has an external, third surface 224 that is adjacent to the external, first surface 216(1) of the interposer substrate 202. The metal interconnects 220 are exposed from the third surface 224 of the package substrate 206. The first metal interconnects 208(1) of the interposer substrate 202 are configured such that they align in the vertical direction (Z-axis direction) to respective metal interconnects 220 of the package substrate 206 so that the first metal interconnects 208(1) of the interposer substrate 202 can be coupled to the metal interconnects 220 of the package substrate 206. Thus, the metal interconnects 220 of the package substrate 206 also intersect the respective vertical axes A₁-A₇ that intersect their coupled first metal interconnects 208(1) to have pin compatibility between the interposer substrate 202 and the package substrate 206. Similarly, the die 204 has an external, fourth surface 226 that is adjacent to the external, second surface 216(2) of the interposer substrate 202. The die interconnects 218 are exposed from the fourth surface 226 of the die 204. The second metal interconnects 208(2) of the interposer substrate 202 are configured such that they align in the vertical direction (Z-axis direction) to respective die interconnects 218 of the die 204 so that the second metal interconnects 208(2) of the interposer substrate 202 can be coupled to the die interconnects 218 of the die 204. Thus, the die interconnects 218 of the die 204 also intersect the respective vertical axes A₁-A₇ that intersect their coupled second metal interconnects 208(2) to have pin compatibility between the interposer substrate 202 and the die 204. Thus, by this arrangement, the pin compatibility between the die interconnects 218 of the die 204 and the external, metal interconnects 220 of the package substrate 206 is maintained even with the presence of the intervening interposer substrate 202.

In this manner, the interposer substrate 202 maintain interconnect compatibility to the die 204 and package substrate 206 if the die 204 and package substrate 206 have a pattern of die interconnects 218 and external metal interconnects 220 that are designed to align with each other when coupled to each other. For example, the die 204 and package substrate 206 may be designed to be directly coupled to each other in an IC package that does not include the interposer substrate 202. Thus, the interposer substrate 202, by including vertically aligned external, first and second metal interconnects 208(1), 208(2), can be used to electrically couple the die 204 to the package sub state 206 without having to change the layout design of the die interconnects 218 of the die(s) and the external metal interconnects 220 of the package substrate 206.

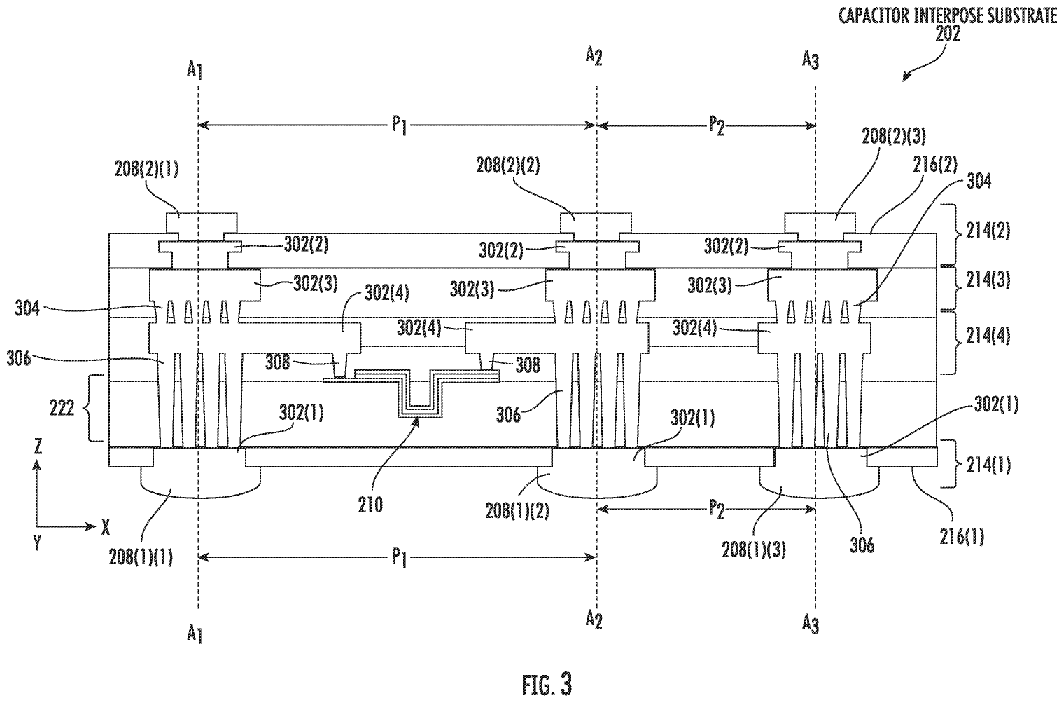

FIG. 3 is a side view of exemplary interposer substrate 202 in the IC package 200 in FIG. 2 to illustrate further exemplary details and features that can be provided in the interposer substrate 202. As shown in FIG. 3, the first metal interconnects 208(1)(1), 208(1)(2) have a first pitch P₁ in a second direction (X-axis direction) orthogonal to the first direction (Z-axis direction) in which the first metal interconnects 208(1)(1), 208(1)(2) are vertically aligned. The first metal interconnects 208(1)(2), 208(1)(3) have a first pitch P₂ between them in the second direction (X-axis direction). In this example, because of the vertical alignment in the vertical direction (Z-axis direction) of the respective first metal interconnects 208(1)(1)-208(1)(3) exposed from the first surface 216(1), with second metal interconnects 208(2)(1)-208(2)(3) exposed from the second surface 216(2), the second metal interconnects 208(2)(1), 208(2)(2) also have the first pitch P₁ in a second direction (X-axis direction). The second metal interconnects 208(2)(2), 208(2)(3) also have the second pitch P₂ between them in the second direction (X-axis direction). Note that the respective first metal interconnects 208(1)(1)-208(1)(3) and second metal interconnects 208(2)(1)-208(2)(3) also have pitches in the second horizontal direction (Y-axis direction) that may also be the same between adjacent vertically aligned first and second metal interconnects 208(1)(1)-208(1)(3), 208(2)(1)-208(2)(3).

With continuing reference to FIG. 3, in this example, the first metallization layer 214(1) of the interposer substrate 202 has a plurality of first metal lines 302(1) each coupled to a first metal interconnect 208(1)(1)-208(1)(3). The second metallization layer 214(2) of the interposer substrate 202 has a plurality of second metal lines 302(2) each coupled to a second metal interconnect 208(2)(1)-208(2)(3). The interposer substrate 202 in FIG. 3 also includes a plurality of additional metallization layers 214(3), 214(4) that are disposed between the second metallization layer 214(2) and the substrate layer 222, and that each have metal lines 302(3), 302(4) to provide interconnections and routing of signals to the second metal interconnects 208(2)(1)-208(2)(3) and/or to the capacitor 210. Vias 304 interconnect the metal lines 302(3), 302(4) between the metallization layers 214(3), 214(4). Vias 306 are also included in the substrate layer 222 to provide pass through connections in the metallization layers 214(2)-214(4) coupled to the second metal interconnects 208(2)(1)-208(2)(3) and coupled to the respective first metallization layer 214(1) coupled to the respective first metal interconnects 208(1)(1)-208(1)(3). The interposer substrate 202 could also have additional metallization layers disposed between the first metallization layer 214(1) and the substrate layer 222 to provide further signal routing in the package substrate 206. Additional vias 308 are provided to provide connections between metal lines 302(4) and the capacitor 210 to provide an electrical connection between the capacitor 210 and the first and second metal interconnects 208(1)(1), 208(2)(1) in this example,

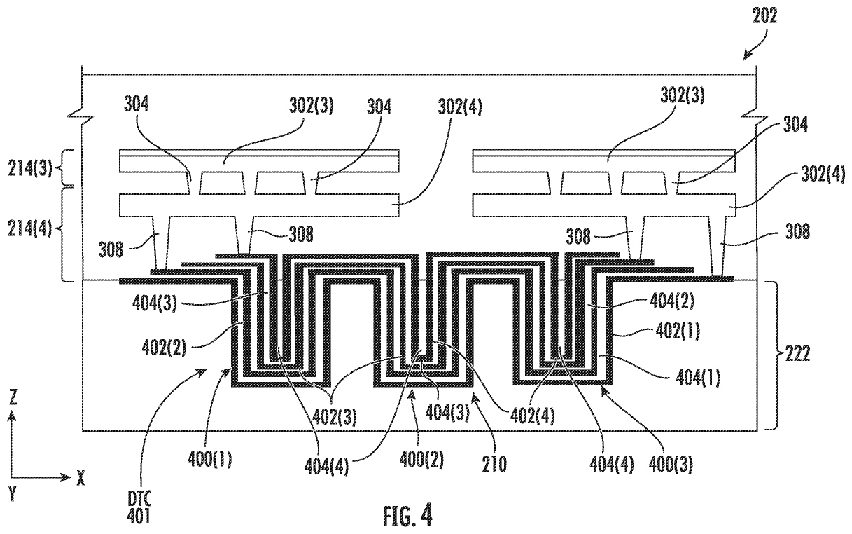

FIG. 4 is a side view of a portion of the interposer substrate 202 in FIGS. 2 and 3 and illustrating the capacitor 210 provided in the form of a DTC 401. As shown in FIG. 4, trenches 400(1)-400(3) are disposed in the substrate layer 222. Four metallization layers 402(1)-402(4) are disposed in the trenches 400(1)-400(3) adjacent to each other. Dielectric layers 404(1)-404(4) are disposed between the respective adjacent metallization layers 402(1)-402(4) in the trenches 400(1)-404(4). The second and fourth metallization layers 402(1)-404(4) are coupled to the respective vias 308 in the fourth metallization layer 214(4) to couple the DTC 401 to the metal lines 302(3), 302(2) in the interposer substrate 202.

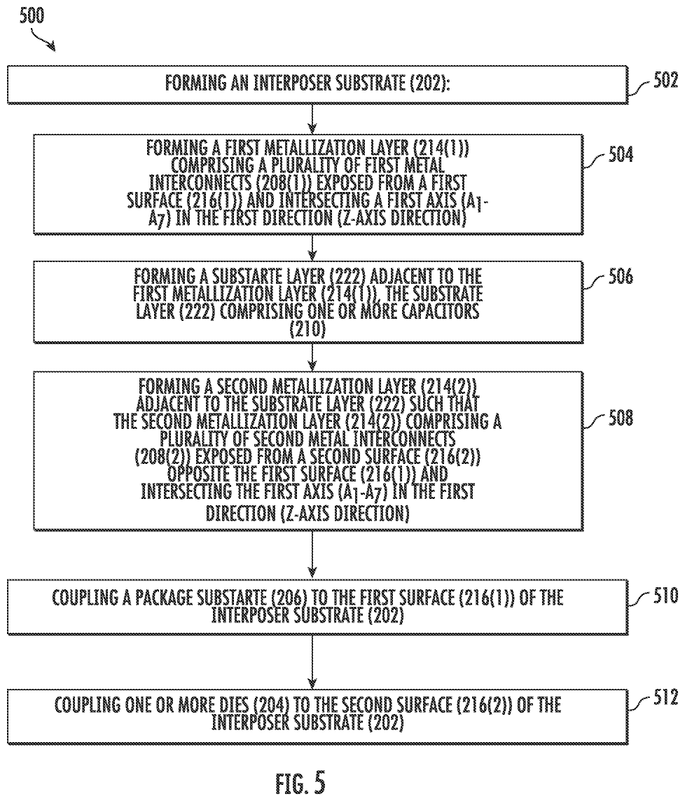

FIG. 5 is a flowchart illustrating an exemplary fabrication process 500 of fabricating an IC package that includes a capacitor interposer substrate coupled to and disposed between a die and a package substrate, wherein the capacitor interposer substrate has aligned external interconnects to maintain interconnect compatibility between the die(s) and the package substrate, including, but not limited to, the IC package 200 and the interposer substrate 202 in FIGS. 2-4. The fabrication process 500 is discussed in reference to the IC package 200 and interposer substrate 202 in FIGS. 2-4, but the fabrication process 500 is not limited to fabricating the IC package 200 and interposer substrate 202 in FIGS. 2-4.

In this regard, a first step in the fabrication process 500 is forming a capacitor interposer substrate 202 (block 502 in FIG. 5). Forming the interposer substrate 202 can include forming a first metallization layer 214(1) comprising a plurality of first metal interconnects 208(1) exposed from a first surface 216(1) and intersecting a first axis A₁-A₇ in the first direction (Z-axis direction) (block 504 in FIG. 5). Forming the interposer substrate 202 can also include forming a substrate layer 222 adjacent to the first metallization layer 214(1), the substrate layer 222 comprising one or more capacitors 210 (block 506 in FIG. 5). Forming the interposer substrate 202 can also include forming a second metallization layer 214(2) adjacent to the substrate layer 222 such that the substrate layer 222 is disposed between the first metallization layer 214(1) and the second metallization layer 214(2) in a first direction (Z-axis direction), the second metallization layer 214(2) comprising a plurality of second metal interconnects 208(2) exposed from a second surface 216(2) opposite the first surface 216(1) and intersecting the first axis A₁-A₇ in the first direction (Z-axis direction) (block 508 in FIG. 5). The fabrication process 500 can also include coupling a package substrate 206 to the first surface 216(1) of the interposer substrate 202 (block 510 in FIG. 5). The fabrication process 500 can also include coupling one or more dies 204 to the second surface 216(2) of the interposer substrate 202 (block 512 in FIG. 5).

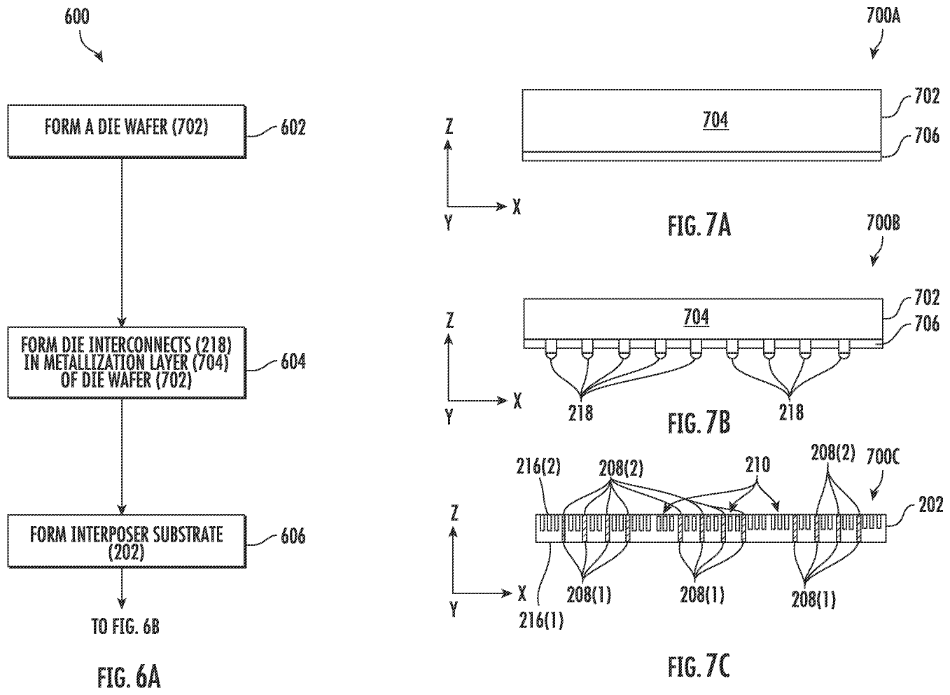

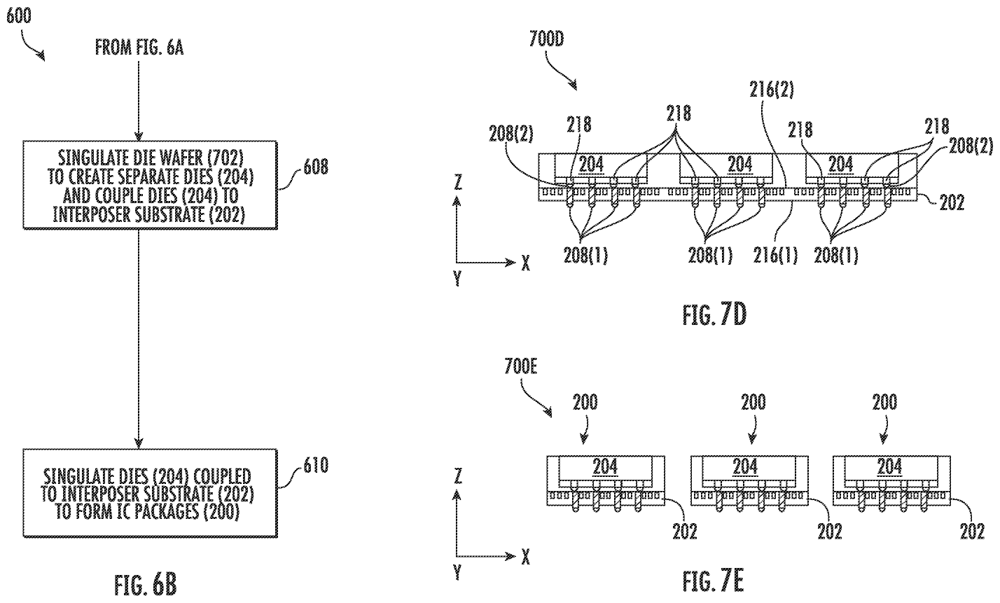

An IC package that includes a capacitor interposer substrate coupled to and disposed between a die and a package substrate, wherein the capacitor interposer substrate has aligned external interconnects, including, but not limited to, the IC package 200 and capacitor interposer substrate 202 in FIGS. 2-4, and can be fabricated in other fabrication processes. For example, FIGS. 6A and 6B are a flowchart illustrating the exemplary fabrication process 600 of fabricating an IC package that includes a capacitor interposer substrate coupled to and disposed between a die and a package substrate, wherein capacitor interposer substrate has aligned external interconnects. FIGS. 7A-7E illustrate exemplary fabrication stages 700A-700E during fabrication of the IC package according to the fabrication process 600 in FIGS. 6A and 6B. The fabrication process 600 in FIGS. 6A and 6B is discussed below with reference to the fabrication stages 700A-700E in FIGS. 7A-7E, which are in reference to the IC package 200 in FIGS. 2-4, but such is not limited to the IC package 200 in FIGS. 2-41n this regard, FIG. 7A illustrates a first fabrication stage 700A in FIG. 7A in the fabrication process 600 of forming a die wafer 702 (block 602 in FIG. 6A). The die wafer 702 will serve as the basis for creating individual dies 204 that can be singulated from the die wafer 702 and then placed individually on an interposer substrate 202 to form separate IC packages 200. As shown in FIG. 7A, the die wafter 702 includes a semiconductor layer 704 and metallization layer(s) 706 formed by a back-end-of-line (BEOL) fabrication process. Then, as shown in the fabrication stage 700B in FIG. 7B, the die interconnects 218 are formed in the metallization layer 706 of the die wafer 702 (block 604 in FIG. 6A). Then, to prepare to fabricate the IC package 200, as shown in fabrication stage 700C in FIG. 7C, a next step in the fabrication process 600 is to form the interposer substrate 202 with is embedded capacitors 210 and first and second metal interconnects 208(1), 208(2) exposed through its respective external, first and second surfaces 216(1), 216(2) (block 606 in FIG. 6A).

Then, as shown in fabrication stage 700D in FIG. 7E, the die wafer 702 in the fabrication stage 700B in FIG. 7B is singulated to create separate dies 204 (block 608 in FIG. 6B). For example, the separate dies 204 may be segregated based on their corner performance, so that dies 204 of a similar or higher performance can be used to form IC packages 200 that include the capacitor interposer substrate 202. The singulated dies 204 are then placed on the second surface 216(2) of the interposer substrate 202 (block 608 in FIG. 6B). Then, as shown in the fabrication stage 700E in FIG. 7E, the dies 204 coupled to the interposer substrate 202 are then singulated to form IC packages 200 (block 610 in FIG. 6B). The IC packages 200 do not show package substrates 206, but the IC packages 200 can be coupled to respective package substrates like the package substrates 206 in FIGS. 2-4.

It should be understood that the terms “first,” “second,” “third,” etc., where used herein, are relative terms and are not meant to limit or imply a strict orientation. It should also be understood that that the terms “top,” “above,” “bottom,” “below,” where used herein, are relative terms and are not meant to limit or imply a strict orientation. A “top” referenced element does not always need to be oriented to be above a “bottom” referenced element with respect to ground, and vice versa. An element referenced as “top” or “bottom” may be on top or bottom relative to that example only and the particular illustrated example. An element referenced as “above” or “below” another element does not have to be with respect to ground, and vice versa. An element referenced as “above” or “below” may be above or below such other referenced element, relative to that example only and the particular illustrated example. The term “adjacent” between elements does not necessarily require such elements to be physically connected or directly adjacent to each other without the presence of intervening elements.

IC packages that include a capacitor interposer substrate coupled to and disposed between a die and a package substrate, wherein the capacitor interposer substrate has aligned external interconnects, including, but not limited to, the IC package 200 in FIGS. 2-4 and 7A-7E, and fabricated according to any of the fabrication processes 500, 600 in FIGS. 5-6B, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

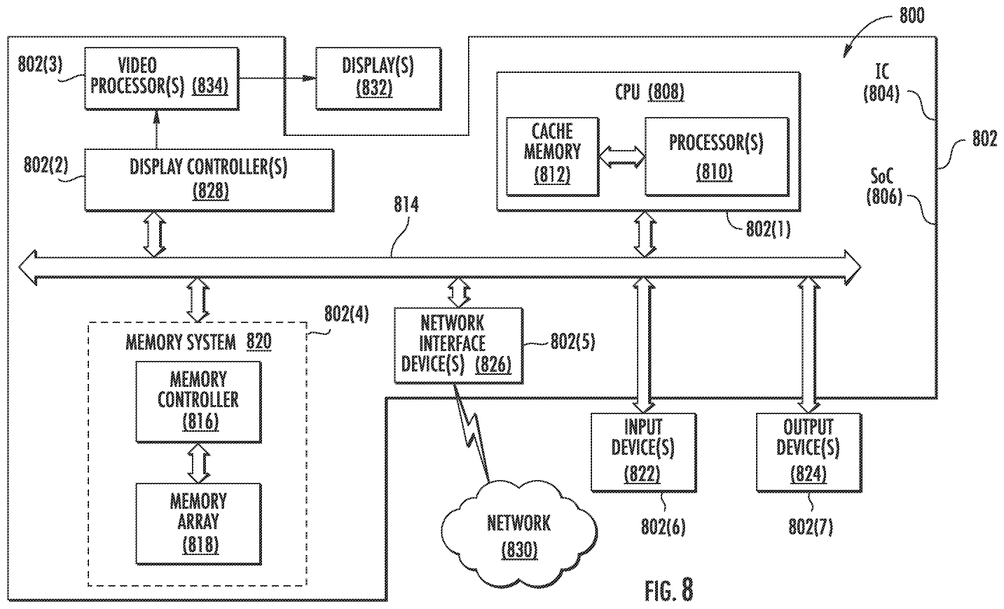

In this regard, FIG. 8 illustrates an example of a processor-based system 800 that can include one or more IC packages 802, 802(1)-802(7) that includes a capacitor interposer substrate coupled to and disposed between a die and a package substrate, wherein the capacitor interposer substrate has aligned external interconnects, including, but not limited to, the IC package 200 in FIGS. 2-4 and 7A-7E, and fabricated according to any of the fabrication processes 500, 600 in FIGS. 5-6B, and according to any aspects disclosed herein. For example, the inductor packages 802(1)-802(7) may be employed as part of a power regulation circuit. In this example, the processor-based system 800 may be formed as an IC 804, and as part of an IC package such as system-on-a-chip (SoC). The processor-based system 800 includes a central processing unit (CPU) 808 that includes one or more processors 810, which may also be referred to as CPU cores or processor cores. The CPU 808 may have cache memory 812 coupled to the CPU 808 for rapid access to temporarily stored data. The CPU 808 is coupled to a system bus 814 and can intercouple master and slave devices included in the processor-based system 800. As is well known, the CPU 808 communicates with these other devices by exchanging address, control, and data information over the system bus 814. For example, the CPU 808 can communicate bus transaction requests to a memory controller 816, as an example of a slave device. Although not illustrated in FIG. 8, multiple system buses 814 could be provided, wherein each system bus 814 constitutes a different fabric.

Other master and slave devices can be connected to the system bus 814. As illustrated in FIG. 8, these devices can include a memory system 820 that includes the memory controller 816 and a memory array(s) 818, one or more input devices 822, one or more output devices 824, one or more network interface devices 826, and one or more display controllers 828, as examples. The input device(s) 822 can include any type of input device, including, but not limited to, input keys, switches, voice processors, etc. The output device(s) 824 can include any type of output device, including, but not limited to, audio, video, other visual indicators, etc. The network interface device(s) 826 can be any device configured to allow exchange of data to and from a network 830. The network 830 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 826 can be configured to support any type of communications protocol desired.

The CPU 808 may also be configured to access the display controller(s) 828 over the system bus 814 to control information sent to one or more displays 832. The display controller(s) 828 sends information to the display(s) 832 to be displayed via one or more video processor(s) 834, which processes the information to be displayed into a format suitable for the display(s) 832. The display(s) 832 can include any type of display, including, but not limited to, a cathode ray tube (CRT), a liquid crystal display (LCD), a plasma display, a light emitting diode (LED) display, etc.

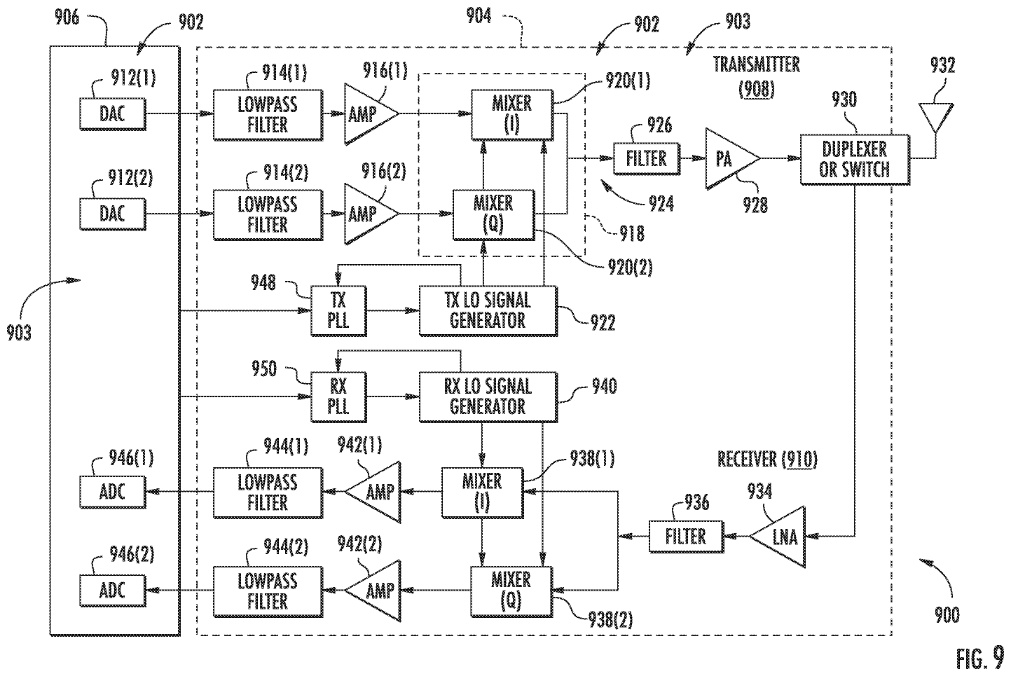

FIG. 9 illustrates an exemplary wireless communications device 900 that includes electrical components formed from one or more ICs 902, wherein any of the ICs 902 can be included in an IC package 903. The IC package 903 can include an IC package that includes a capacitor interposer substrate coupled to and disposed between a die and a package substrate, wherein the capacitor interposer substrate has aligned external interconnects, including, but not limited to, the IC package 200 in FIGS. 2-4 and 7A-7E, and fabricated according to any of the fabrication processes 500, 600 in FIGS. 5-6B, and according to any aspects disclosed herein. The wireless communications device 900 may include or be provided in any of the above referenced devices, as examples. As shown in FIG. 9, the wireless communications device 900 includes a transceiver 904 and a data processor 906. The data processor 906 may include a memory to store data and program codes. The transceiver 904 includes a transmitter 908 and a receiver 910 that support bi-directional communications. In general, the wireless communications device 900 may include any number of transmitters 908 and/or receivers 910 for any number of communication systems and frequency bands. All or a portion of the transceiver 904 may be implemented on one or more analog ICs, RF ICs (RFICs), mixed-signal ICs, etc.

The transmitter 908 or the receiver 910 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 910. In the direct-conversion architecture, a signal is frequency-converted between RF and baseband in one stage. The super-heterodyne and direct-conversion architectures may use different circuit blocks and/or have different requirements. In the wireless communications device 900 in FIG. 9, the transmitter 908 and the receiver 910 are implemented with the direct-conversion architecture.

In the transmit path, the data processor 906 processes data to be transmitted and provides I and Q analog output signals to the transmitter 908. In the exemplary wireless communications device 900, the data processor 906 includes digital-to-analog converters (DACs) 912(1), 912(2) for converting digital signals generated by the data processor 906 into the I and Q analog output signals, e.g., I and Q output currents, for further processing.

Within the transmitter 908, lowpass filters 914(1), 914(2) filter the I and Q analog output signals, respectively, to remove undesired signals caused by the prior digital-to-analog conversion. Amplifiers (AMPs) 916(1), 916(2) amplify the signals from the lowpass filters 914(1), 914(2), respectively, and provide I and Q baseband signals. An upconverter 918 upconverts the I and Q baseband signals with I and Q transmit (TX) local oscillator (LO) signals through mixers 920(1), 920(2) from a TX LO signal generator 922 to provide an upconverted signal 924. A filter 926 filters the upconverted signal 924 to remove undesired signals caused by the frequency upconversion as well as noise in a receive frequency band. A power amplifier (PA) 928 amplifies the upconverted signal 924 from the filter 926 to obtain the desired output power level and provides a transmit RF signal. The transmit RF signal is routed through a duplexer or switch 930 and transmitted via an antenna 932.

In the receive path, the antenna 932 receives signals transmitted by base stations and provides a received RF signal, which is routed through the duplexer or switch 930 and provided to a low noise amplifier (LNA) 934. The duplexer or switch 930 is designed to operate with a specific receive (RX)-to-TX duplexer frequency separation, such that RX signals are isolated from TX signals. The received RF signal is amplified by the LNA 934 and filtered by a filter 936 to obtain a desired RF input signal. Downconversion mixers 938(1), 938(2) mix the output of the filter 936 with I and Q RX LO signals (i.e., LO_I and LO_Q) from an RX LO signal generator 940 to generate I and Q baseband signals. The I and Q baseband signals are amplified by AMPs 942(1), 942(2) and further filtered by lowpass filters 944(1), 944(2) to obtain I and Q analog input signals, which are provided to the data processor 906. In this example, the data processor 906 includes analog-to-digital converters (ADCs) 946(1), 946(2) for converting the analog input signals into digital signals to be further processed by the data processor 906.

In the wireless communications device 900 of FIG. 9, the TX LO signal generator 922 generates the I and Q TX LO signals used for frequency upconversion, while the RX LO signal generator 940 generates the I and Q RX LO signals used for frequency downconversion. Each LO signal is a periodic signal with a particular fundamental frequency. A TX phase-locked loop (PLL) circuit 948 receives timing information from the data processor 906 and generates a control signal used to adjust the frequency and/or phase of the TX LO signals from the TX LO signal generator 922. Similarly, an RX PLL circuit 950 receives timing information from the data processor 906 and generates a control signal used to adjust the frequency and/or phase of the RX LO signals from the RX LO signal generator 940.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are also described in the following numbered clauses:

1. An integrated circuit (IC) package, comprising:
an interposer substrate comprising a first surface and a second surface opposite of the first surface;
the interposer substrate further comprising:
   a first metallization layer comprising a plurality of first metal interconnects exposed from the first surface;
   a second metallization layer comprising a plurality of second metal interconnects exposed from the second surface; and
   a substrate layer disposed between the first metallization layer and the second metallization layer in a first direction, the substrate layer comprising one or more capacitors;
   each first metal interconnect of the plurality of first metal interconnects intersecting a first axis in the first direction that intersects a second metal interconnect of the plurality of second metal interconnects;
a package substrate coupled to the first surface of the interposer substrate; and
a die coupled to the second surface of the interposer substrate.
   2. The IC package of clause 1, wherein each first metal interconnect of the plurality of first metal interconnects are aligned with the second metal interconnect of the plurality of second metal interconnects in the first direction.
   3. The IC package of clause 1, wherein each first metal interconnect of the plurality of first metal interconnects partially overlap the second metal interconnect of the plurality of second metal interconnects in the first direction.
   4. The IC package of any of clauses 1-3, wherein:
the plurality of first metal interconnects has a first pitch in a second direction orthogonal to the first direction; and
the plurality of second metal interconnects have the first pitch in the second direction.
   5. The IC package of clause 4, wherein:
the plurality of first metal interconnects has a second pitch in a third direction orthogonal to the second direction; and
the plurality of second metal interconnects having the second pitch in the third direction.
   6. The IC package of any of clauses 1-5, wherein the package substrate comprises:
a third surface adjacent to the first surface of the interposer substrate; and
a plurality of third metal interconnects exposed from the third surface;
each of the plurality of third metal interconnects coupled to the first metal interconnect of the plurality of first metal interconnects.
   7. The IC package of clause 6, wherein each of the plurality of third metal interconnects intersects the first axis in the first direction that intersects the first metal interconnect of the plurality of first metal interconnects.
   8. The IC package of clause 7, wherein the die comprises:
a fourth surface adjacent to the second surface of the interposer substrate; and
a plurality of die interconnects exposed from the fourth surface;
each of the plurality of die interconnects coupled to the second metal interconnect of the plurality of second metal interconnects.
   9. The IC package of clause 8, wherein each of the plurality of die interconnects intersects the first axis in the first direction that intersects the second metal interconnect of the plurality of second metal interconnects.
   10. The IC package of any of clauses 1-7, wherein the die comprises:
a third surface adjacent to the second surface of the interposer substrate; and
a plurality of die interconnects exposed from the third surface;
each of the plurality of die interconnects coupled to the second metal interconnect of the plurality of second metal interconnects.
   11. The IC package of clause 10, wherein each of the plurality of die interconnects intersects the first axis in the first direction that intersects the second metal interconnect of the plurality of second metal interconnects.
   12. The IC package of any of clauses 1-11, wherein at least one capacitor of the one or more capacitors is coupled to a second metal interconnect of the plurality of second metal interconnects.
   13. The IC package of any of clauses 1-12, wherein at least one capacitor of the one or more capacitors is coupled to a first metal interconnect of the plurality of first metal interconnects.
   14. The IC package of any of clauses 1-13, wherein each of the one or more capacitors comprise:
a third metallization layer disposed in a trench in the substrate layer;
a fourth metallization layer disposed adjacent to the third metallization layer in the trench in the substrate layer; and
a dielectric layer disposed in the trench between the third metallization layer and the fourth metallization layer;
wherein:
   the third metallization layer is coupled to a first, second metal interconnect of the plurality of second metal interconnects; and
   the fourth metallization layer is coupled to a second, second metal interconnect of the plurality of second metal interconnects.
      15. The IC package of any of clauses 1-14, wherein:
the first metallization layer comprises a plurality of first metal lines each coupled to a first metal interconnect of the plurality of first metal interconnects;
and the second metallization layer comprises a plurality of second metal lines each coupled to a second metal interconnect of the plurality of second metal interconnects.
   16. The IC package of any of clauses 1-15, wherein the interposer substrate further comprises a third metallization layer disposed between the second metallization layer and the substrate layer in the first direction;
the third metallization layer comprising a plurality of third metal interconnects each coupled to a via of a plurality of vias each coupled to a second metal interconnect of the plurality of second metal interconnects; and
each via of the plurality of vias coupled to a capacitor of the one or more capacitors.
   17. The IC package of any of clauses 1-16, wherein the interposer substrate further comprises a third metallization layer disposed between the first metallization layer and the substrate layer in the first direction;
the third metallization layer comprising a plurality of third metal interconnects each coupled to a via of a plurality of vias each coupled to a second metal interconnect of the plurality of second metal interconnects; and
each via of the plurality of vias coupled to a capacitor of the one or more capacitors.
   18. The IC package of any of clauses 1-17 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
   19. A method of fabricating a plurality of IC packages, comprising for each IC package of one or more IC packages:
forming an interposer substrate comprising:
   forming a first metallization layer comprising a plurality of first metal interconnects exposed from a first surface and intersecting a first axis in a first direction;
   forming a substrate layer adjacent to the first metallization layer, the substrate layer comprising one or more capacitors; and
   forming a second metallization layer adjacent to the substrate layer such that the substrate layer is disposed between the first metallization layer and the second metallization layer in the first direction, the second metallization layer comprising a plurality of second metal interconnects exposed from a second surface opposite the first surface and intersecting the first axis in the first direction;
coupling a package substrate to the first surface of the interposer substrate; and
coupling one or more dies to the second surface of the interposer substrate.
   20. The method of clause 19, wherein:
forming the first metallization layer further comprises forming the first metallization layer comprising the plurality of first metal interconnects having a first pitch in a second direction orthogonal to the first direction; and
forming the second metallization layer further comprises forming the second metallization layer comprising the plurality of second metal interconnects the first pitch in the second direction.
   21. The method of clause 19 or 20, wherein coupling the package substrate to the first surface of the interposer substrate comprises coupling a plurality of third metal interconnects exposed from a third surface of the package substrate adjacent to the first surface of the interposer substrate to a first metal interconnect of the plurality of first metal interconnects.
   22. The method of any of clauses 19-21, wherein coupling the one or more dies to the second surface of the interposer substrate comprises coupling a plurality of die interconnects exposed from a third surface of the one or more dies adjacent to the second surface of the interposer substrate, to the second metal interconnect of the plurality of second metal interconnects.
   23. The method of clause 22, wherein:
forming the interposer substrate further comprising at least one capacitor of the one or more capacitors coupled to a second metal interconnect of the plurality of second metal interconnects; and
coupling the one or more dies to the second surface of the interposer substrate further comprises coupling the one or more dies to the at least one capacitor of the one or more capacitors each coupled to a second metal interconnect of the plurality of second metal interconnects.
   24. The IC package of any of clauses 19-23, wherein forming the substrate layer further comprises, for each of the one or more capacitors:
forming a trench in the substrate layer;
forming a third metallization layer in the trench;
forming a dielectric layer in the trench adjacent to the third metallization layer;
forming a fourth metallization layer in the trench and adjacent to the dielectric layer such that the dielectric layer is disposed between the third metallization layer and the fourth metallization layer; and
further comprising, for each capacitor of the one or more capacitors:
   coupling a first, second metal interconnect of the plurality of second metal interconnects the third metallization layer; and
   coupling a second, second metal interconnect of the plurality of second metal interconnects to the fourth metallization layer.
      25. The method of any of clauses 19-24, further comprising forming an interposer substrate wafer comprising the interposer substrate for each IC package of the plurality of IC packages.
      26. The method of clause 25, further comprising forming the one or more dies comprises forming a plurality of dies comprising forming a die wafer, comprising;
forming a semiconductor layer;
forming a third metallization layer adjacent to the semiconductor layer; and
forming a plurality of die interconnects in the third metallization layer, the plurality of die interconnects coupled to the semiconductor layer.
   27. The method of clause 26, further comprising singulating the die wafer into the plurality of dies.
   28. The method of clause 27, further comprising placing each of the plurality of dies on the second surface of the interposer substrate wafer to form the plurality of IC packages.
   29. The method of clause 28, further comprising singulating the interposer substrate wafer between adjacent dies of the plurality of dies to provide the plurality of IC packages.

1. An integrated circuit (IC) package, comprising:
an interposer substrate comprising a first surface and a second surface opposite of the first surface;
the interposer substrate further comprising:
a first metallization layer comprising a plurality of first metal interconnects exposed from the first surface;
a second metallization layer comprising a plurality of second metal interconnects exposed from the second surface; and
a substrate layer disposed between the first metallization layer and the second metallization layer in a first direction, the substrate layer comprising one or more capacitors;
each first metal interconnect of the plurality of first metal interconnects intersecting a first axis in the first direction that intersects a second metal interconnect of the plurality of second metal interconnects;
a package substrate coupled to the first surface of the interposer substrate; and
a die coupled to the second surface of the interposer substrate.

2. The IC package of claim 1, wherein each first metal interconnect of the plurality of first metal interconnects are aligned with the second metal interconnect of the plurality of second metal interconnects in the first direction.

3. The IC package of claim 1, wherein each first metal interconnect of the plurality of first metal interconnects partially overlap the second metal interconnect of the plurality of second metal interconnects in the first direction.

4. The IC package of claim 1, wherein:
the plurality of first metal interconnects has a first pitch in a second direction orthogonal to the first direction; and
the plurality of second metal interconnects have the first pitch in the second direction.

5. The IC package of claim 4, wherein:
the plurality of first metal interconnects has a second pitch in a third direction orthogonal to the second direction; and
the plurality of second metal interconnects having the second pitch in the third direction.

6. The IC package of claim 1, wherein the package substrate comprises:
a third surface adjacent to the first surface of the interposer substrate; and
a plurality of third metal interconnects exposed from the third surface;
each of the plurality of third metal interconnects coupled to the first metal interconnect of the plurality of first metal interconnects.

7. The IC package of claim 6, wherein each of the plurality of third metal interconnects intersects the first axis in the first direction that intersects the first metal interconnect of the plurality of first metal interconnects.

8. The IC package of claim 7, wherein the die comprises:
a fourth surface adjacent to the second surface of the interposer substrate; and
a plurality of die interconnects exposed from the fourth surface;
each of the plurality of die interconnects coupled to the second metal interconnect of the plurality of second metal interconnects.

9. The IC package of claim 8, wherein each of the plurality of die interconnects intersects the first axis in the first direction that intersects the second metal interconnect of the plurality of second metal interconnects.

10. The IC package of claim 1, wherein the die comprises:
a third surface adjacent to the second surface of the interposer substrate; and
a plurality of die interconnects exposed from the third surface;
each of the plurality of die interconnects coupled to the second metal interconnect of the plurality of second metal interconnects.

11. The IC package of claim 10, wherein each of the plurality of die interconnects intersects the first axis in the first direction that intersects the second metal interconnect of the plurality of second metal interconnects.

12. The IC package of claim 1, wherein at least one capacitor of the one or more capacitors is coupled to a second metal interconnect of the plurality of second metal interconnects.

13. The IC package of claim 1, wherein at least one capacitor of the one or more capacitors is coupled to a first metal interconnect of the plurality of first metal interconnects.

14. The IC package of claim 1, wherein each of the one or more capacitors comprise:
a third metallization layer disposed in a trench in the substrate layer;
a fourth metallization layer disposed adjacent to the third metallization layer in the trench in the substrate layer; and
a dielectric layer disposed in the trench between the third metallization layer and the fourth metallization layer;
wherein:
the third metallization layer is coupled to a first, second metal interconnect of the plurality of second metal interconnects; and
the fourth metallization layer is coupled to a second, second metal interconnect of the plurality of second metal interconnects.

15. The IC package of claim 1, wherein:
the first metallization layer comprises a plurality of first metal lines each coupled to a first metal interconnect of the plurality of first metal interconnects; and
the second metallization layer comprises a plurality of second metal lines each coupled to a second metal interconnect of the plurality of second metal interconnects.

16. The IC package of claim 1, wherein the interposer substrate further comprises a third metallization layer disposed between the second metallization layer and the substrate layer in the first direction;
the third metallization layer comprising a plurality of third metal interconnects each coupled to a via of a plurality of vias each coupled to a second metal interconnect of the plurality of second metal interconnects; and
each via of the plurality of vias coupled to a capacitor of the one or more capacitors.

17. The IC package of claim 1, wherein the interposer substrate further comprises a third metallization layer disposed between the first metallization layer and the substrate layer in the first direction;
the third metallization layer comprising a plurality of third metal interconnects each coupled to a via of a plurality of vias each coupled to a second metal interconnect of the plurality of second metal interconnects; and
each via of the plurality of vias coupled to a capacitor of the one or more capacitors.

18. The IC package of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

19. A method of fabricating a plurality of IC packages, comprising for each IC package of one or more IC packages:
forming an interposer substrate comprising:
forming a first metallization layer comprising a plurality of first metal interconnects exposed from a first surface and intersecting a first axis in a first direction;
forming a substrate layer adjacent to the first metallization layer, the substrate layer comprising one or more capacitors; and
forming a second metallization layer adjacent to the substrate layer such that the substrate layer is disposed between the first metallization layer and the second metallization layer in the first direction, the second metallization layer comprising a plurality of second metal interconnects exposed from a second surface opposite the first surface and intersecting the first axis in the first direction;
coupling a package substrate to the first surface of the interposer substrate; and
coupling one or more dies to the second surface of the interposer substrate.

20. The method of claim 19, wherein:
forming the first metallization layer further comprises forming the first metallization layer comprising the plurality of first metal interconnects having a first pitch in a second direction orthogonal to the first direction; and
forming the second metallization layer further comprises forming the second metallization layer comprising the plurality of second metal interconnects the first pitch in the second direction.

21. The method of claim 19, wherein coupling the package substrate to the first surface of the interposer substrate comprises coupling a plurality of third metal interconnects exposed from a third surface of the package substrate adjacent to the first surface of the interposer substrate to a first metal interconnect of the plurality of first metal interconnects.

22. The method of claim 19, wherein coupling the one or more dies to the second surface of the interposer substrate comprises coupling a plurality of die interconnects exposed from a third surface of the one or more dies adjacent to the second surface of the interposer substrate, to the second metal interconnect of the plurality of second metal interconnects.

23. The method of claim 22, wherein:
forming the interposer substrate further comprising at least one capacitor of the one or more capacitors coupled to a second metal interconnect of the plurality of second metal interconnects; and
coupling the one or more dies to the second surface of the interposer substrate further comprises coupling the one or more dies to the at least one capacitor of the one or more capacitors each coupled to a second metal interconnect of the plurality of second metal interconnects.

24. The method of claim 19, wherein forming the substrate layer further comprises, for each of the one or more capacitors:
forming a trench in the substrate layer;
forming a third metallization layer in the trench;
forming a dielectric layer in the trench adjacent to the third metallization layer;
forming a fourth metallization layer in the trench and adjacent to the dielectric layer such that the dielectric layer is disposed between the third metallization layer and the fourth metallization layer; and
further comprising, for each capacitor of the one or more capacitors:
coupling a first, second metal interconnect of the plurality of second metal interconnects the third metallization layer; and
coupling a second, second metal interconnect of the plurality of second metal interconnects to the fourth metallization layer.

25. The method of claim 19, further comprising forming an interposer substrate wafer comprising the interposer substrate for each IC package of the plurality of IC packages.

26. The method of claim 25, further comprising forming the one or more dies comprises forming a plurality of dies comprising forming a die wafer, comprising;
forming a semiconductor layer;
forming a third metallization layer adjacent to the semiconductor layer; and
forming a plurality of die interconnects in the third metallization layer, the plurality of die interconnects coupled to the semiconductor layer.

27. The method of claim 26, further comprising singulating the die wafer into the plurality of dies.

28. The method of claim 27, further comprising placing each of the plurality of dies on the second surface of the interposer substrate wafer to form the plurality of IC packages.

29. The method of claim 28, further comprising singulating the interposer substrate wafer between adjacent dies of the plurality of dies to provide the plurality of IC packages.
